(19) United States
(12) Patent Application Publication
(10) Pub. No.: US 2018/0131869 A1
(43) Pub. Date: May 10, 2018

(54) METHOD FOR PROCESSING IMAGE AND ELECTRONIC DEVICE SUPPORTING THE SAME

(71) Applicant: Samsung Electronics Co., Ltd., Suwon-si (KR)

(72) Inventors: Do Han KIM, Suwon-si (KR); Jae Hyoung PARK, Yongin-si (KR); Sung Kyu LEE, Suwon-si (KR); Kwang Tai KIM, Yongin-si (KR); Ha Joong PARK, Suwon-si (KR); Dong Hyun YEOM, Bucheon-si (KR); Jong Hoon WON, Suwon-si (KR)

(21) Appl. No.: 15/804,263

(22) Filed: Nov. 6, 2017

(30) Foreign Application Priority Data
Nov. 9, 2016 (KR) 10-2016-0149027

(51) Int. Cl. H04N 5/232; G06K 9/00; H04N 5/235; H04N 9/73

(52) U.S. Cl. CPC H04N 5/23219; G06K 9/00288; H04N 9/73; H04N 5/23212; H04N 5/2353; H04N 5/23229

(57) ABSTRACT

An electronic device for image processing and a method thereof are provided. The electronic device includes a lens part, an image sensor, a memory, and at least one image processor. The at least one image processor for processing an image signal of the image sensor is configured to collect first image data through the image sensor at a first time, collect first recognition information about a plurality of objects recognized from the first image data, collect second image data through the image sensor at a second time, collect second recognition information about an object recognized from the second image data, and determine an object of interest of a user based on a difference between the first recognition information and the second recognition information.

### CROSS-REFERENCE TO RELATED APPLICATION(S)

This application claims the benefit under 35 U.S.C. § 119(a) of a Korean patent application filed on Nov. 9, 2016 in the Korean Intellectual Property Office and assigned Serial number 10-2016-0149027, the entire disclosure of which is hereby incorporated by reference.

### TECHNICAL FIELD

The present disclosure relates to a method for processing an image and an electronic device supporting the same.

### BACKGROUND

Various types of photographing devices (or imaging devices) such as a digital single-lens reflex camera (DSLR), a mirror-less digital camera, and the like are being released. Also, an electronic device such as a smartphone, a tablet personal computer (PC), or the like includes a camera module and provides a function of photographing a picture or a video. The imaging device or the electronic device may automatically adjust a focus (e.g., auto focus (AF)) or may automatically adjust an exposure (e.g., auto exposure (AE)). Even though a user does not separately set the focus or exposure, the imaging device or the electronic device may capture a photo or a video having an exposure of a proper level.

The above information is presented as background information only to assist with an understanding of the present disclosure. No determination has been made, and no assertion is made, as to whether any of the above might be applicable as prior art with regard to the present disclosure.

### SUMMARY

Aspects of the present disclosure are to address at least the above-mentioned problems and/or disadvantages and to provide at least the advantages described below. Accordingly, an aspect of the present disclosure is to provide a method for processing an image and an electronic device supporting the same.

In the case where an electronic device performs auto focus (AF) in a state where a plurality of objects (faces of persons) are included on a screen, the electronic device may determine that an object that is the closest to the electronic device, an object that occupies the largest area, an object close to the center of the screen, or the like is the object of interest of a user, and may operate in the manner of focusing on the determined object of interest. In the case where the plurality of objects (faces of persons) are included on the screen, the electronic device may determine the object of interest of the user by using a simple algorithm to capture a photo or a video while focusing on an object different from an object that the user intends.

Alternatively, the electronic device may store an image associated with the object of interest in advance to determine the object of interest with reference to the stored image. In this case, inconveniently, the user performs a procedure of registration, deletion, or change of the object of interest repeatedly.

In addition, the electronic device may change an exposure through AF Bracketing to perform AF. In this case, the performance may be limited in a night shot.

In accordance with an aspect of the present disclosure, an electronic device is provided. The electronic device includes a lens part for collecting light from outside of the electronic device, an image sensor for changing light passing through the lens part to an electrical signal, a memory, and at least one image processor for processing an image signal of the image sensor. The at least one image processor for processing an image signal of the image sensor is configured to collect first image data through the image sensor at a first time, collect first recognition information about a plurality of objects recognized from the first image data, collect second image data through the image sensor at a second time, collect second recognition information about an object recognized from the second image data, and determine an object of interest of a user based on a difference between the first recognition information and the second recognition information.

According to various embodiments of the present disclosure, a method for processing an image and an electronic device supporting the same may perform AF and auto exposure (AE), auto white balance (AWB), color correction, or the like on an object of interest (or subject, hereafter) selected depending on user's actual intent when capturing a plurality of objects.

According to various embodiments of the present disclosure, a method for processing an image and an electronic device supporting the same may select the object of interest, which a user intends, by using a database associated with an object, in which the user is interested.

According to various embodiments of the present disclosure, a method for processing an image and an electronic device supporting the same may perform AF on the object, which the user actually intends, by using the movement of the electronic device, image comparison, or the like.

According to various embodiments of the present disclosure, a method for processing an image and an electronic device supporting the same may store information about the object of interest of the user over a network to rapidly determine the object, in which the user is interested, in the case where a capture environment is changed.

According to various embodiments of the present disclosure, a method for processing an image and an electronic device supporting the same may update the database based on words, for which the user searches, to perform AF on a subject, in which the user is interested and which is captured first.

Other aspects, advantages, and salient features of the disclosure will become apparent to those skilled in the art from the following detailed description, which, taken in conjunction with the annexed drawings, discloses various embodiments of the present disclosure.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 is a view illustrating a configuration of an electronic device according to various embodiments of the present disclosure;

FIG. 2 is a block diagram illustrating a configuration of an image processing unit, according to various embodiments of the present disclosure;

FIG. 3A is a flowchart illustrating an image processing method, according to various embodiments of the present disclosure;

FIG. 3B is a flowchart illustrating determining of an object of interest in a capture process of a still image, according to various embodiments of the present disclosure;

FIG. 3C is a flowchart illustrating determining of an object of interest in a capture process of a video, according to various embodiments of the present disclosure;

FIG. 4 is a table illustrating storage of an object database, according to various embodiments of the present disclosure;

FIG. 5 is a view of a photo capture, according to various embodiments of the present disclosure;

FIG. 6 is a flowchart illustrating an update of an object database using search information of a user, according to various embodiments of the present disclosure;

FIG. 7 is a view of a user interface for displaying a priority of an object of interest, according to various embodiments of the present disclosure;

FIG. 8 illustrates the electronic device in a network environment according various embodiments of the present disclosure; and

FIG. 9 illustrates a block diagram of the electronic device according to various embodiments of the present disclosure.

Throughout the drawings, it should be noted that like reference numbers are used to depict the same or similar elements, features, and structures.

### DETAILED DESCRIPTION

The following description with reference to the accompanying drawings is provided to assist in a comprehensive understanding of various embodiments of the present disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the present disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the present disclosure. Accordingly, it should be apparent to those skilled in the art that the following description of various embodiments of the present disclosure is provided for illustration purpose only and not for the purpose of limiting the present disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

In the disclosure disclosed herein, the expressions “have”, “may have”, “include” and “comprise”, or “may include” and “may comprise” used herein indicate existence of corresponding features (for example, elements such as numeric values, functions, operations, or components) but do not exclude presence of additional features.

In the disclosure disclosed herein, the expressions “A or B”, “at least one of A or/and B”, or “one or more of A or/and B”, and the like used herein may include any and all combinations of one or more of the associated listed items. For example, the term “A or B”, “at least one of A and B”, or “at least one of A or B” may refer to all of the case (1) where at least one A is included, the case (2) where at least one B is included, or the case (3) where both of at least one A and at least one B are included.

The terms, such as “first”, “second”, and the like used herein may refer to various elements of various embodiments of the present disclosure, but do not limit the elements. For example, such terms are used only to distinguish an element from another element and do not limit the order and/or priority of the elements. For example, a first user device and a second user device may represent different user devices irrespective of sequence or importance. For example, without departing the scope of the present disclosure, a first element may be referred to as a second element, and similarly, a second element may be referred to as a first element.

It will be understood that when an element (for example, a first element) is referred to as being “(operatively or communicatively) coupled with/to” or “connected to” another element (for example, a second element), it can be directly coupled with/to or connected to the other element or an intervening element (for example, a third element) may be present. In contrast, when an element (for example, a first element) is referred to as being “directly coupled with/to” or “directly connected to” another element (for example, a second element), it should be understood that there are no intervening element (for example, a third element).

According to the situation, the expression “configured to” used herein may be used as, for example, the expression “suitable for”, “having the capacity to”, “designed to”, “adapted to”, “made to”, or “capable of”. The term “configured to (or set to)” must not mean only “specifically designed to” in hardware. Instead, the expression “a device configured to” may mean that the device is “capable of” operating together with another device or other components. Central processing unit (CPU), for example, a “processor configured to (or set to) perform A, B, and C” may mean a dedicated processor (for example, an embedded processor) for performing a corresponding operation or a generic-purpose processor (for example, a CPU or an application processor (AP)) which may perform corresponding operations by executing one or more software programs which are stored in a memory device.

Terms used in this specification are used to describe specified embodiments of the present disclosure and are not intended to limit the scope of the present disclosure. The terms of a singular form may include plural forms unless otherwise specified. Unless otherwise defined herein, all the terms used herein, which include technical or scientific terms, may have the same meaning that is generally understood by a person skilled in the art. It will be further understood that terms, which are defined in a dictionary and commonly used, should also be interpreted as is customary in the relevant related art and not in an idealized or overly formal detect unless expressly so defined herein in various embodiments of the present disclosure. In some cases, even if terms are terms which are defined in the specification, they may not be interpreted to exclude embodiments of the present disclosure.

An electronic device according to various embodiments of the present disclosure may include at least one of smartphones, tablet personal computers (PCs), mobile phones, video telephones, electronic book readers, desktop PCs, laptop PCs, netbook computers, workstations, servers, personal digital assistants (PDAs), portable multimedia players (PMPs), Moving Picture Experts Group (MPEG-1 or MPEG-2) audio layer 3 (MP3) players, mobile medical devices, cameras, and wearable devices. According to various embodiments of the present disclosure, the wearable devices may include accessories (for example, watches, rings, bracelets, ankle bracelets, glasses, contact lenses, or head-mounted devices (HMDs)), cloth-integrated types (for example, electronic clothes), body-attached types (for example, skin pads or tattoos), or implantable types (for example, implantable circuits).

In some embodiments of the present disclosure, the electronic device may be one of home appliances. The home appliances may include, for example, at least one of a digital versatile disc (DVD) player, an audio, a refrigerator, an air conditioner, a cleaner, an oven, a microwave oven, a washing machine, an air cleaner, a set-top box, a home automation control panel, a security control panel, a television (TV) box (for example, Samsung HomeSync™, Apple TV™, or Google TV™), a game console (for example, Xbox™ or PlayStation™), an electronic dictionary, an electronic key, a camcorder, or an electronic panel.

In another embodiment of the present disclosure, the electronic device may include at least one of various medical devices (for example, various portable medical measurement devices (a blood glucose meter, a heart rate measuring device, a blood pressure measuring device, and a body temperature measuring device), a magnetic resonance angiography (MRA), a magnetic resonance imaging (MRI) device, a computed tomography (CT) device, a photographing device, and an ultrasonic device), a navigation system, a global navigation satellite system (GNSS), an event data recorder (EDR), a flight data recorder (FDR), a vehicular infotainment device, electronic devices for vessels (for example, a navigation device for vessels and a gyro compass), avionics, a security device, a vehicular head unit, an industrial or home robot, an automatic teller's machine (ATM) of a financial company, a point of sales (POS) of a store, or an internet of things (for example, a bulb, various sensors, an electricity or gas meter, a spring cooler device, a fire alarm device, a thermostat, an electric pole, a toaster, a sporting apparatus, a hot water tank, a heater, and a boiler).

According to some embodiments of the present disclosure, the electronic device may include at least one of a furniture or a part of a building/structure, an electronic board, an electronic signature receiving device, a projector, or various measurement devices (for example, a water service, electricity, gas, or electric wave measuring device). In various embodiments of the present disclosure, the electronic device may be one or a combination of the aforementioned devices. The electronic device according to some embodiments of the present disclosure may be a flexible electronic device. Further, the electronic device according to an embodiment of the present disclosure is not limited to the aforementioned devices, but may include new electronic devices produced due to the development of technologies.

Hereinafter, electronic devices according to an embodiment of the present disclosure will be described with reference to the accompanying drawings. The term “user” used herein may refer to a person who uses an electronic device or may refer to a device (for example, an artificial electronic device) that uses an electronic device.

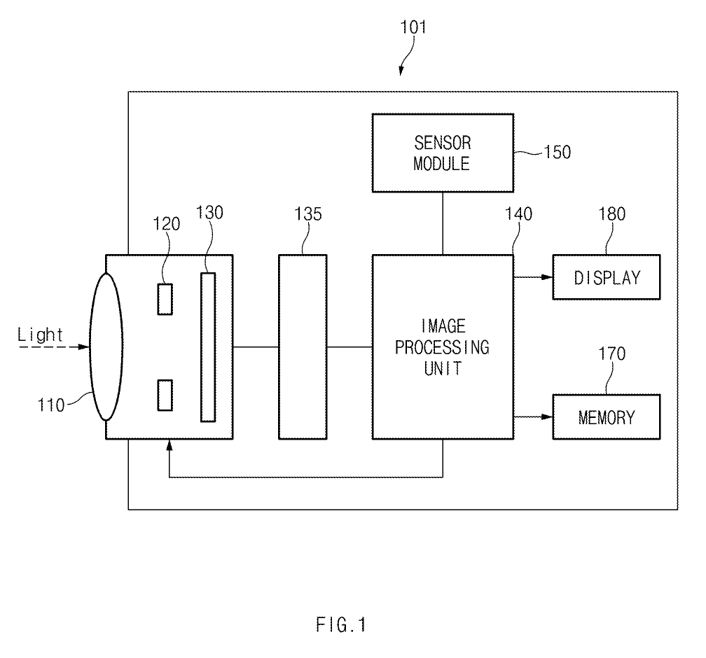

FIG. 1 is a view illustrating a configuration of an electronic device according to various embodiments of the present disclosure.

Referring to FIG. 1, an electronic device 101 may be a device that collects light reflected from an external subject to capture a picture or a video. The electronic device 101 may include a lens part 110, a shutter part 120, an image sensor 130, a sensor interface 135, an image processing unit 140 (e.g., at least one image processor), a sensor module (or a sensor) 150, a memory 170, and a display 180.

The lens part 110 according to various embodiments of the present disclosure may collect light reaching a device from a subject. An image may be formed on the image sensor 130 by the collected light. The lens part 110 according to various embodiments of the present disclosure may be composed of a plurality of lenses (e.g., a dual camera, an array camera, or the like).

The shutter part 120 according to various embodiments of the present disclosure may adjust the amount of light exposed to the image sensor 130 through slit driving. For example, the shutter part 120 may be implemented with a shutter having a mechanical shape or may be implemented with an electronic shutter through a control of a sensor. For another example, the shutter part 120 may be a shutter that is electronically implemented with only a last film (front shutter film).

The image sensor 130 (or an imaging device or an imaging device unit) according to various embodiments of the present disclosure may convert light into electronic image data by using a photoelectric conversion effect. The image data may be transferred to the image processing unit 140 through the sensor interface 135. The image sensor 130 may include a group of pixels arranged two-dimensionally and may convert light into electronic image data at each pixel. The image sensor 130 may read electronic image data according to the photoelectric conversion effect recorded in each pixel (read-out). The image sensor 130 according to various embodiments of the present disclosure may be composed of a plurality of image sensors.

The sensor interface 135 may perform an interface between the image sensor 130 and the image processing unit 140.

Through various processing operations, the image processing unit 140 (or a processor or an application processor) may output image data collected by the image sensor 130 to the display 180 or may store the collected image data in the memory 170. In various embodiments, the image processing unit 140 may include a pre-processing unit (e.g., Pre image signal processor (ISP)), a main processing unit (e.g., ISP or a peripheral controller), a post-processing unit (e.g., Post-ISP), or the like. The pre-processing unit (e.g., Pre ISP) may execute a function of image matching, gamma processing, or the like. For example, in the case where there is blurring between a plurality of images photographed continuously, the pre-processing unit may remove or reduce a blurring component through the image matching process. After correcting and composing signals received from the pre-processing unit, the main processing unit may generate the whole image signal. The main processing unit may perform a function of controlling overall operations such as signal amplification, signal conversion, signal processing, and the like. The post-processing unit may store an image signal provided from the main processing unit in the memory 170 or may output the image signal to the display 180. The post-processing unit may convert and transfer the image signal into a format supported by the memory 170 or the display 180.

According to various embodiments, the image processing unit 140 may analyze the image data collected by the image sensor 130 to generate a signal for controlling the lens part 110 or the image sensor 130. A focus may be adjusted through the signal such that an object (or a subject) in which a user is interested is clearly captured.

The image processing unit 140 may control the lens part 110 or the image sensor 130 depending on default settings or the selection of the user (e.g., the selection of an object on a Live View) for the purpose of adjusting the focus.

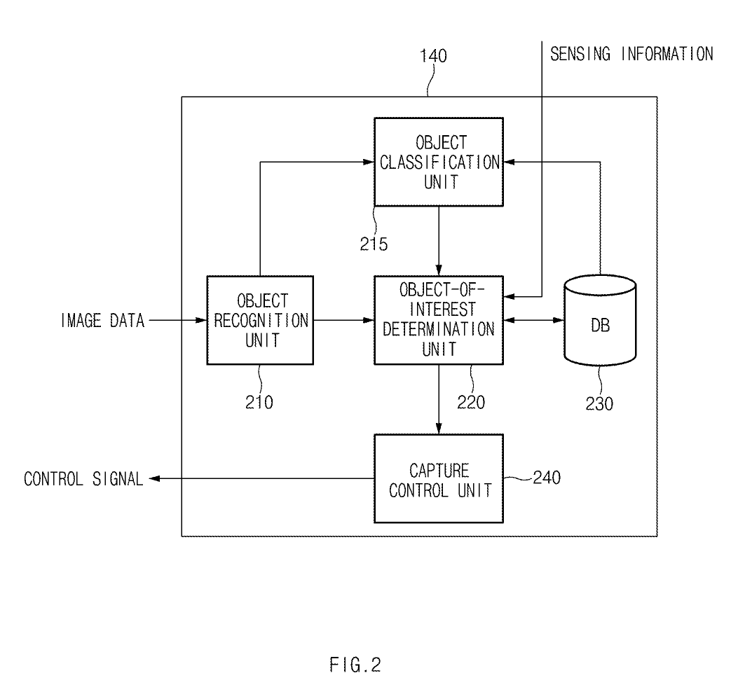

In the case where the movement of the electronic device 101 is sensed through the sensor module 150 (or in the case where the degree of the movement exceeds a specified value), the image processing unit 140 may compare an image before the occurrence of movement with an image after the occurrence of movement, for the purpose of determining an object of interest of the user. Additional information associated with the configuration of the image processing unit 140 and processing for focal adjustment will be provided through FIGS. 2 to 7.

The sensor module 150 may sense movement information of the electronic device 101 (e.g., a movement direction, a movement distance, a rotational direction, a rotational degree, or the like), ambient brightness, or the like. The sensor module 150 may provide sensing information to the image processing unit 140. For example, the sensor module 150 may include a gyro sensor, an acceleration sensor, a proximity sensor, an illuminance sensor, or the like to collect information (e.g., ambient brightness, a nearby object, a location of an electronic device, a place of an electronic device, or the like) obtained by sensing an environment at a periphery of the electronic device 101. According to various embodiments, the sensor module 150 may include a location recognition module such as a global positioning system (GPS), or the like. According to various embodiments, the sensor module 150 may include another image sensor (not illustrated). For example, the sensor module 150 may collect illuminance information or the like by using a separate image sensor (e.g., sub-camera) that is distinguished from the image sensor 130 (e.g., a main camera).

The memory 170 may store an image processed through the image processing unit 140. The display 180 may output image data processed in the image processing unit 140 so as to be verified by a user.

FIG. 2 is a block diagram illustrating a configuration of an image processing unit, according to various embodiments of the present disclosure. FIG. 2 is, but is not limited to, an example. Each of elements may be integrated with each other or may be separated from each other. The image processing unit 140 may be implemented with one chip (e.g., an application processor) or may be composed of a plurality of chips. For example, an object recognition unit 210, an object classification unit 215, and an object-of-interest determination unit 220 may be one module or may be modules, each of which is divided. For another example, the sensor module 150 and an object database 230 may be disposed in an external device (e.g., a server).

Referring to FIG. 2, the image processing unit 140 according to various embodiments may include the object recognition unit 210, the object classification unit 215, the object-of-interest determination unit 220, the object database 230, and a capture control unit 240.

The object recognition unit 210 according to various embodiments may recognize various objects based on image data. For example, the object recognition unit 210 may recognize a face of a person, an object, a pattern, a design, or the like. In the case where the object recognition unit 210 recognizes the face, the object recognition unit 210 may determine the location, size, or the like of the face based on a relative location of eyes, a nose, a mouth, or the like of the person in the image data. The object recognition unit 210 may use a variety of object recognition algorithms.

In the embodiment, the object recognition unit 210 may recognize an object based on information stored in a separate database.

According to various embodiments, the image processing unit 140 may further include a data processing unit (not illustrated). The data processing unit (not illustrated) may transmit data, which is read out from the image sensor 130, in the form capable of being easily recognized by the object recognition unit 210. For example, the data processing unit (not illustrated) may transmit data, which corresponds to a partial area (e.g., region of interest (ROI)) of the center, from among the whole pixel data or may transmit data, to the object recognition unit 210. For another example, the data processing unit (not illustrated) may transmit image data, which is from an edge occurrence point to an edge end point in the image data, to the object recognition unit 210.

The object classification unit 215 according to various embodiments may classify an object detected by the object recognition unit 210, with reference to the object database 230. The object classification unit 215 may determine whether the object recognized by the object recognition unit 210 is matched to an object stored in the object database 230. The object classification unit 215 may provide the matching result to the object-of-interest determination unit 220. The object-of-interest determination unit 220 may provide information about the determined object of interest to the capture control unit 240.

The object-of-interest determination unit 220 according to various embodiments may analyze input image data to determine the object of interest of a user. The object-of-interest determination unit 220 may determine the object of interest of a user of objects recognized by the object recognition unit 210, with reference to the object database 230. In the case where there is an object, which is matched to the object stored in the object database 230, from among the recognized objects, the object-of-interest determination unit 220 may determine the object of interest depending on the priority of the corresponding object. For example, the object-of-interest determination unit 220 may verify an object, which is matched to an object stored in the object database 230, from among first to fourth objects extracted from image data collected at a first time T1. In the case where the first object is matched and the second to fourth objects are not matched, the object-of-interest determination unit 220 may determine that the first object is the object of interest. For another example, in the case where the first object and the second object are matched and the third object and the fourth object are not matched, the object-of-interest determination unit 220 may determine that each of the first object and the second object is the object of interest or may determine that an object of the highest priority is the object of interest.

According to various embodiments, in the case where the object-of-interest determination unit 220 receives sensing information (e.g., movement information, rotation information, or the like of the electronic device 101) through the sensor module 150, the object-of-interest determination unit 220 may compare pieces of recognition information, which are obtained by recognizing an object included in image data at a specified time period (e.g., 0.2 seconds), with each other. The object-of-interest determination unit 220 may determine the object of interest based on the sensing information.

For example, in the case where the movement of the electronic device 101 occurs, the object-of-interest determination unit 220 may verify a change in the object recognized before and after the movement for the purpose of determining that an object recognized continuously, an object displayed on a screen longer, or the like is the object of interest of the user.

According to various embodiments, the object-of-interest determination unit 220 may assign a weight of each of recognized objects and may store the assigned result in the object database 230. The object-of-interest determination unit 220 may generate data of newly recognized object and may reflect the weight of the object stored in advance to change a priority.

According to various embodiments, in the case where the storage of a still image is completed, in the case where video capture ends, or in the case where the storage of a video is completed, the object-of-interest determination unit 220 may update the weight, which is changed in a capture process, in the object database 230.

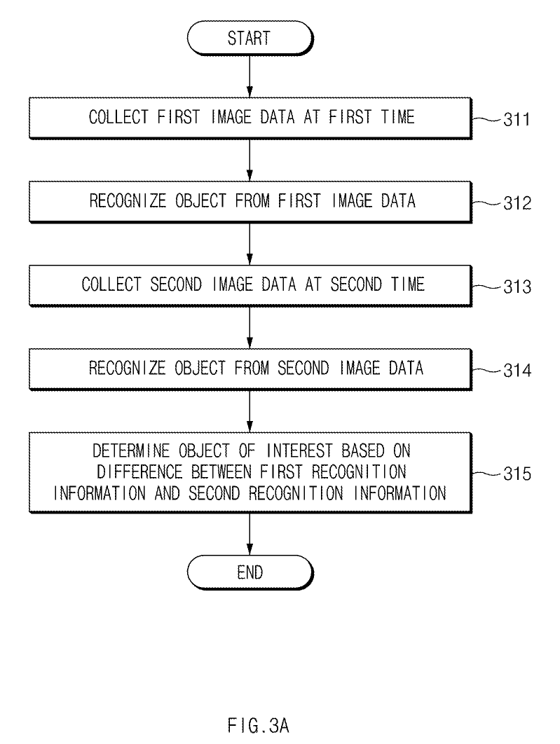

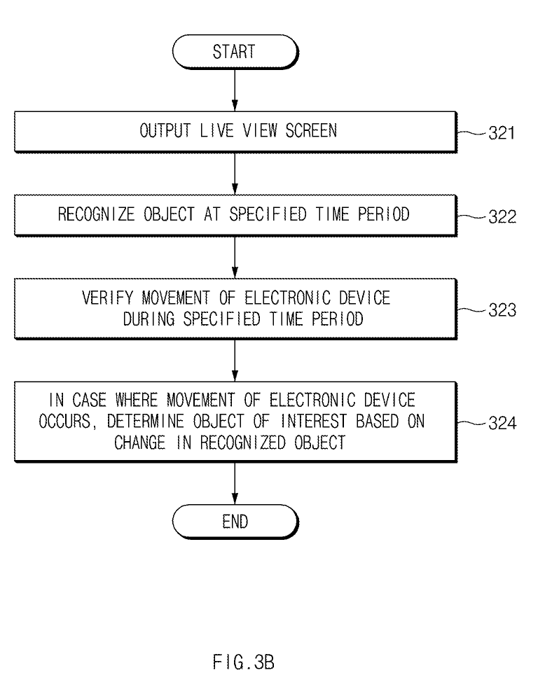

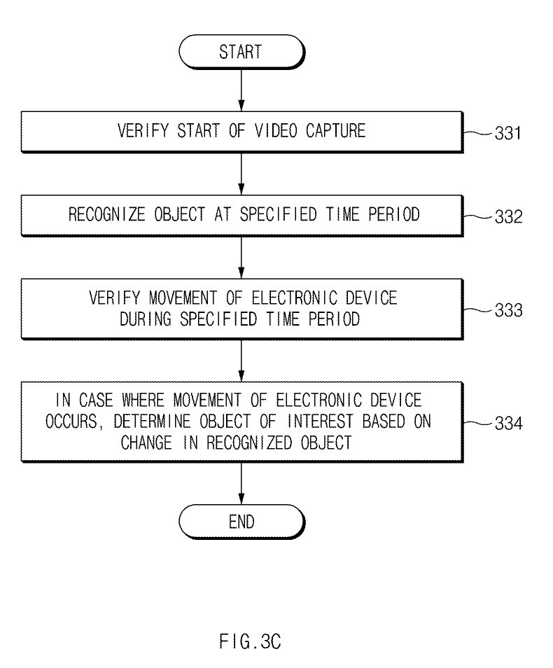

Additional information about a method in which the object-of-interest determination unit 220 determines an object of interest may be provided through FIGS. 3A, 3B, 3C, 4, 5, 6 and 7.

The object database 230 may store information about an object recognized through the object recognition unit 210 or a recognizable object. The object database 230 may store information necessary to recognize an object, the priority (or a priority score) of each object, an appearance frequency of each object, or the like.

The capture control unit 240 may generate a control signal for controlling the lens part 110 or the image sensor 130. The capture control unit 240 may control the lens part 110 or the image sensor 130 such that auto focus (AF), auto white balance (AWB), an expose, color modification, or the like is performed based on the object of interest determined by the object-of-interest determination unit 220.

In an embodiment, in the case where a still image is captured, the capture control unit 240 may calculate the depth of each object of interest and an AF Point based on the object of interest transmitted by the object-of-interest determination unit 220. The capture control unit 240 may perform AF, AWB, expose, color modification, or the like, which is centered on the object of interest, depending on a preset value.

In another embodiment, in the case where a video is captured, the capture control unit 240 may perform the AF, the AWB, the expose, the color modification, or the like, which centers the object of interest, depending on the value, which is set in advance based on the object of interest transmitted by the object-of-interest determination unit 220, and may reflect the video being captured.

FIG. 3A is a flowchart illustrating an image processing method, according to various embodiments of the present disclosure.

Referring to FIG. 3A, in operation 311, the image processing unit 140 may collect first image data through the image sensor 130 at a first time T1. For example, the first image data may be a Live View image that is being output through the display 180 after a camera app is executed. For another example, the first image data may be an image that is being output through the display 180 in a process of capturing a video after a user presses a video capture button.

In operation 312, the image processing unit 140 may collect first recognition information about a plurality of objects recognized from the first image data. For example, the first recognition information may include a type of an object, a location of a feature point, whether the recognized object is matched to an object stored in the object database 230, or the like. In an embodiment, the image processing unit 140 may store the first recognition information in a buffer or the object database 230.

In operation 313, the image processing unit 140 may collect second image data through the image sensor 130 at a second time T2 after the first time T1. The first time T1 and the second time T2 may maintain a specified time period T (e.g., 0.2 seconds). According to various embodiments, the image sensor 130 may continuously collect image data during the specified time period T.

According to various embodiments, the sensor module 150 may sense movement of the electronic device 101 that occurs between the first time T1 and the second time T2. In an embodiment, the sensor module 150 may continuously sense the movement of the electronic device 101 before the first image data generated according to operation 312 is collected. The sensor module 150 may sense movement information of the electronic device 101 (e.g., a movement direction, a movement distance, a rotational direction, a rotational degree, or the like). The sensor module 150 may provide sensing information to the image processing unit 140. In an embodiment, only when it is determined that the electronic device 101 moves by a specified range or more, the sensor module 150 may provide the sensing information to the image processing unit 140.

In operation 314, the image processing unit 140 may collect second recognition information about the object recognized from the second image data. The object may be maintained, move, or disappear, or the size of the object may be changed, on the screen during the time period T between the first time T1 and the second time T2. Alternatively, even though the object does not move, when the user moves the electronic device 101, the object may be maintained, move, or disappear on the screen, or the size of the object may be changed. When the object moves or the electronic device 101 moves, a difference between first recognition information and second recognition information may occur.

In operation 315, the image processing unit 140 may determine the object of interest of the user based on the difference between the first recognition information and the second recognition information.

According to various embodiments, generally, the case where the user moves the electronic device 101 may be an operation for following an object, in which the user is interested and which the user desires to capture. In the case where the user moves the electronic device 101, the image processing unit 140 may compare an image recognized before the occurrence of movement with an image recognized after the occurrence of movement to determine the object of interest of the user. The image processing unit 140 may determine that an object, which is continuously recognized before the occurrence of movement and after the occurrence of movement, an object displayed on the screen relatively long, an object in which an area displayed on the screen increases, or the like is the object of interest of the user.

According to various embodiments, the image processing unit 140 may assign a weight for determining the object of interest to the recognized object to determine a priority based on the summed weight and may determine the object of interest depending on the priority.

For example, the image processing unit 140 may assign the weight having a relatively high value to an object continuously recognized, an object displayed on a screen longer, an object in which an area displayed on the screen increases, or the like of from among the recognized objects. Alternatively, the image processing unit 140 may assign the weight to an object disposed close to the center of a screen.

For another example, the image processing unit 140 may assign the weight of the preset low value to an object, which is detected less than a specified frequency or specified size, from among the recognized objects.

For another example, after an object being tracked moves to the boundary of Live View or disappears on a Live View screen, in the case where the movement of a camera occurs and the corresponding object is included again in the Live View screen, the image processing unit 140 may increase the weight associated with the corresponding object.

For another example, in the case where a direction in which the object being tracked moves is the same as the movement of the electronic device 101, the image processing unit 140 may increase the weight associated with the corresponding object.

According to various embodiments, in the case where the user touches a specific object to select an AF point, the image processing unit 140 may increase the weight associated with the selected object.

According to various embodiments, the image processing unit 140 may sum a current capture-related weight associated with an object, which is matched to the object stored in the object database 230, from among the recognized objects and a weight of priority information previously stored, for the purpose of determining the object of interest of the user.

According to various embodiments, even though there is no movement of the electronic device 101, the image processing unit 140 may compare the first recognition information and the second recognition information to determine the object of interest of the user. For example, in the case where an object recognized depending on the movement of an object is changed, the image processing unit 140 may determine the object of interest of the user based on the changed object.

According to various embodiments, even though there is no movement of the electronic device 101, the image processing unit 140 may determine the object of interest of the user based on a change in the size of the object of interest. For example, in the case where the size of the object of interest is changed by a user input applied to a display or a button (e.g., the change in a size by zoom-in or zoom-out) in a state where an electronic device is fixed (e.g., in a state where the electronic device is fixed to a tripod, or the like), the image processing unit 140 may determine the object of interest of the user based on an object, the size of which increases.

According to various embodiments, the image processing unit 140 may compare the first recognition information and the second recognition information of the preset ROI to determine the object of interest. The ROI may be determined depending on the selection of the user (e.g., a screen touch) or auto settings (e.g., a partial area of the center of the screen).

According to various embodiments, the image processing unit 140 may generate a control signal for controlling the lens part 110 or the image sensor 130, based on the determined object of interest. The AF, AWB, expose, color modification, or the like may be performed through the control signal.

FIG. 3B is a flowchart illustrating determining of an object of interest in a capture process of a still image, according to various embodiments of the present disclosure. FIG. 3B is, but is not limited to, an example.

Referring to FIG. 3B, in operation 321, the image processing unit 140 may output a Live View screen. The Live View screen may be automatically executed or may be executed by a user input. For example, in the case where a user powers on the electronic device 101, the Live View screen may be automatically executed. For another example, in the case where the user presses a button or executes a camera app, the Live View screen may be executed. The Live View screen may be executed by the call of another application.

In operation 322, the image processing unit 140 may recognize an object at the specified time period T. According to various embodiments, in the case where the electronic device 101 moves at a preset speed or more or at a preset angle or more, the image processing unit 140 may set the time period T for recognizing the object through the sensor module 150 to be short.

In operation 323, the image processing unit 140 may determine whether the movement of the electronic device 101 occurs during the specified time period T (or the movement of the electronic device 101 is not less than (or is greater than) a specified range), through the sensor module 150.

In operation 324, in the case where the movement of the electronic device 101 occurs, the image processing unit 140 may determine an object of interest based on the change in the recognized object.

The image processing unit 140 may calculate the depth and AF Point of each object of interest based on the determined object of interest. The image processing unit 140 may perform AF, AWB, expose, color modification, or the like, which is centered on the object of interest, depending on a preset value.

According to various embodiments, in the case where the movement of the electronic device 101 is not generated (or in the case where the movement of the electronic device 101 is less than (or is not greater than) a specified range), the image processing unit 140 may determine the object of interest based on the location and movement of an object that is located on a current Live View.

According to various embodiments, in the case where the storage of a still image is completed (e.g., in the case where a shutter is pressed, or in the case where a touch button is pressed), the image processing unit 140 may perform a capture reflecting on the set focus, expose, or the like to. The image processing unit 140 may update and store recognition information (e.g., a weight, an appearance frequency, an appearance date, composition information, size information, or the like) changed in a capture process, in the object database 230.

FIG. 3C is a flowchart illustrating determining of an object of interest in a capture process of a video, according to various embodiments of the present disclosure. FIG. 3C is, but is not limited to, an example.

Referring to FIG. 3C, in operation 331, the image processing unit 140 may verify the start of a video capture. For example, in a state where a user executes a camera app, the image processing unit 140 may determine whether the user touches a capture start button, to start the video capture.

In operation 332, after the video capture is started, the image processing unit 140 may recognize an object at a specified time period T.

In operation 333, the image processing unit 140 may determine whether the movement of the electronic device 101 occurs during the specified time period T (or the movement of the electronic device 101 is not less than (or is greater than) a specified range), through the sensor module 150.

In operation 334, in the case where the movement of the electronic device 101 occurs, the image processing unit 140 may determine an object of interest based on the change in the recognized object.

According to various embodiments, in the case where the movement of the electronic device 101 is not generated (or in the case where the movement of the electronic device 101 is less than (or is not greater than) a specified range), the image processing unit 140 may determine the object of interest based on the location and movement of an object is located on an image being currently input.

According to various embodiments, in the case where the capture of a video ends (e.g., in the case where a user touches a capture end button) or in the case where the storage of the video is completed (e.g., in the case where the video is automatically stored after the capture ends, in the case where the user touches a storage button, or the like), the image processing unit 140 may update and store recognition information (e.g., a weight, an appearance frequency, an appearance date, composition information, size information, or the like) changed in a process of capturing the video, in the object database 230. In an embodiment, in the case where the user forcibly stops a video function while not completing the video capture, the image processing unit 140 may not apply the changed recognition information to the object database 230.

According to various embodiments, an image processing method performed in an electronic device includes collecting a first image through an image sensor at a first time, collecting first recognition information about a plurality of objects recognized from the first image, collecting a second image through the image sensor at a second time, collecting second recognition information about an object recognized from the second image, and determining an object of interest of a user based on a difference between the first recognition information and the second recognition information.

According to various embodiments, the image processing method further includes generating a control signal for controlling a lens part or the image sensor, by using the determined object of interest.

According to various embodiments, the image processing method further includes if a capture input associated with a still image is generated, updating priority information about an external object stored in a memory based on the first recognition information and the second recognition information, and if a capture end input or a storage input associated with a video is generated, updating priority information about an external object stored in a memory based on the first recognition information and the second recognition information.

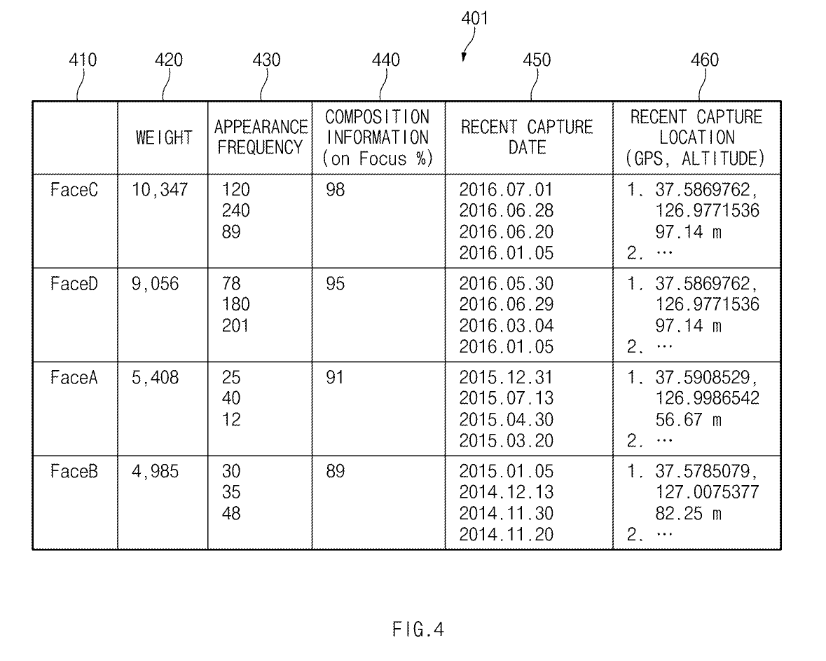

FIG. 4 is a table illustrating storage of an object database, according to various embodiments of the present disclosure. In FIG. 4, an embodiment is exemplified as a face is recognized. However, embodiments may not be limited thereto.

Referring to FIG. 4, an object of interest database (DB) 401 may include information of an object identification code 410, a weight 420 (or priority), an appearance frequency 430, composition information 440, a capture date 450, an appearance location 460, or the like. The item of FIG. 4 is, but is not limited to, an example. For example, the object of interest DB 401 may include information about the sound generated by an object (e.g., a voice or the like).

The object identification code 410 may be a symbol that is uniquely assigned to the object. In the case where there is a newly recognized object, or in the case where there is an object for which a user searches, the object identification code 410 may be added newly.

In the case where a possibility that the recognized object is an object of interest of a user based on data of the appearance frequency 430, the composition information 440, the capture date 450, the appearance location 460, or the like, the weight 420 (or priority) of the corresponding object may increase. For example, in the case where a frequency at which an object is recognized from an image is high, in the case where the object is close to the center of the image, or in the case where an area occupied by the object in the image is great, the weight 420 (or a priority) may increase.

In various embodiments, the appearance frequency 430, the composition information 440, the capture date 450, or the appearance location 460 may be updated based on a still image or a video separately stored by a capture. For example, in the case where the storage of a still image is completed (e.g., in the case where a shutter is pressed, or in the case where a touch button is pressed), the image processing unit 140 may update information about the changed appearance frequency 430, the composition information 440, the capture date 450, or the appearance location 460 in the object of interest DB 401. For another example, in the case where the capture of a video ends (e.g., in the case where the user touches a capture end button) or in the case where the storage of the video is completed (e.g., in the case where the video is automatically stored after the capture ends, in the case where the user touches a storage button, or the like), the image processing unit 140 may update information about the changed appearance frequency 430, the composition information 440, the capture date 450, or the appearance location 460 in the object of interest DB 401.

According to various embodiments, the object of interest DB 401 may be transmitted to an external device (e.g., a server) and may be stored in the external device. If necessary, the user may download the object of interest DB 401 stored in an external server to another electronic device and may use the object of interest DB 401.

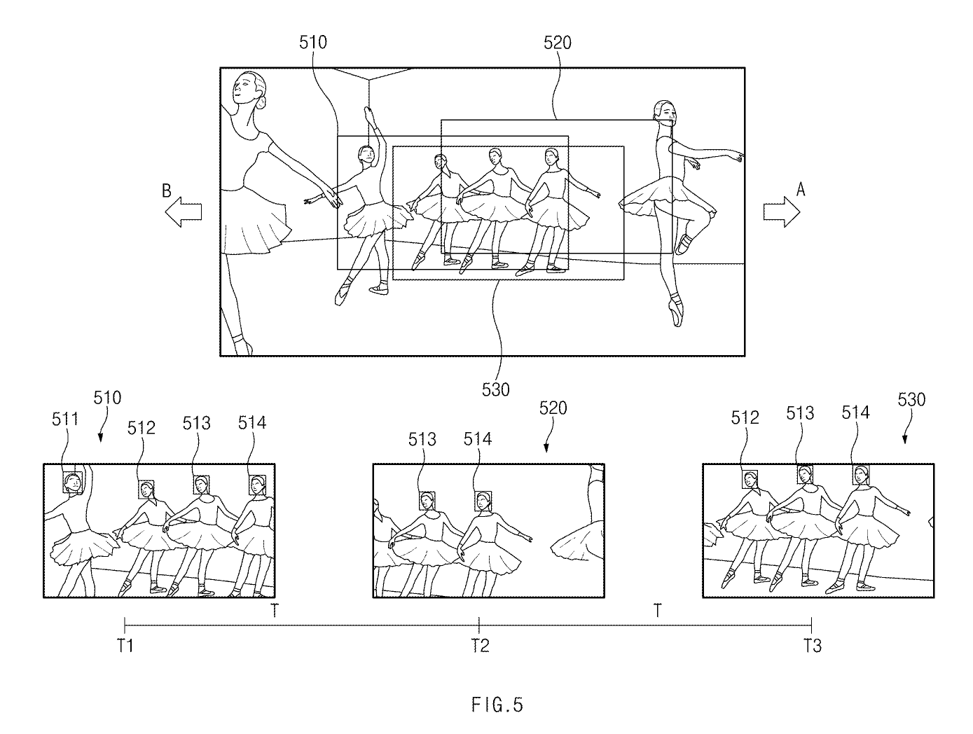

FIG. 5 is a view of a photo capture, according to various embodiments of the present disclosure.

Referring to FIG. 5, a user may capture a subject at a periphery of the user by using the electronic device 101. In the case where a plurality of objects are included on a screen, the user may capture a photo (a still image) or a video while moving along the subject in which the user is interested. Hereinafter, a description will be given with respect to the case where the still image is captured. However, embodiments are not limited thereto.

In the case where the user verifies a first image 510 through the display 180 at a first time T1 when a Live View is started, the image processing unit 140 may recognize first to fourth objects 511 to 514.

According to various embodiments, in the case where there is an object, which is matched to an object stored in advance in the object database 230, from among the first to fourth objects 511 to 514, the image processing unit 140 may determine an object of interest depending on the priority of the corresponding object.

In the case where there is no object matched to an object stored in advance in the object database 230, the same weight may be assigned to all of the first to fourth objects 511 to 514.

The image processing unit 140 may analyze movement information of the electronic device 101 collected through the sensor module 150 to determine whether the electronic device 101 moves by a specified range or more (or out of a specified range).

According to various embodiments, in the case where there is no separate movement, the image processing unit 140 may increase a weight associated with an object, which is continuously maintained in the first image 510, and may store the weight. For example, the weight of the object which disappears from a screen because the object moves may become relatively low. The weight of object, which does not move or moves within a small range, may become relatively high. Alternatively, the weight of the object, the area ratio on the screen of which increases because the object moves to be close to the electronic device 101 or the electronic device 101 moves to be close to the object may increase.

In the case where the user moves the electronic device 101 by a specified range or more and verifies the second image 520 through the display 180 at a second time T2, the image processing unit 140 may recognize the third and fourth objects 513 and 514.

The image processing unit 140 may set the weight of the third and fourth objects 513 and 514, which is recognized in common at the first time T1 and the second time T2, to be relatively high.

According to various embodiments, in the case where the movement direction of the object is the same as (or is synchronized with) the movement direction of a camera, the image processing unit 140 may assign an additional weight to the corresponding object. For example, in the case where the third object 513 of the third and fourth objects 513 and 514 recognized from the second image 520 moves in direction A and the fourth object 514 thereof moves in direction B, the image processing unit 140 may assign the additional weight to the third object 513, the direction of which is the same as direction A in which the electronic device 101 moves.

In the case where the user moves the electronic device 101 again by a specified range or more and verifies the third image 530 through the display 180 at a third time T3, the image processing unit 140 may recognize the second to fourth objects 512 to 514. In this case, the weights of the third and fourth objects 513 and 514 may be continuously maintained in a high state. Since the second object 512 is recognized from the third image 530 again, the weight of the second object 512 may be changed to be higher than the weight of the first object 511 and to be lower than the weight of the third object 513 or the fourth object 514.

According to various embodiments, in the case where the user generates an input for selecting a specific object, the weight of the corresponding object may increase. For example, in the case where the user touches the third object 513 on the screen, the weight of the third object 513 may increase.

According to various embodiments, in the case where the user presses a capture button to store a photo, recognition information about the object changed in a capture process or/and the weight thereof may be updated in the object database 230.

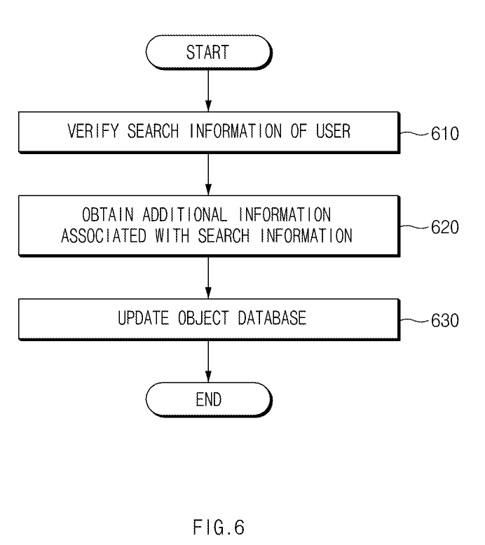

FIG. 6 is a flowchart illustrating an update of an object database using search information of a user, according to various embodiments of the present disclosure.

Referring to FIG. 6, the electronic device 101 may update information about an object of interest of the user based on information for which the user searches. In spite of an object that has not been captured previously or an object that has not been captured at all, the object frequently found by the user through a web browser app may be the object of interest of the user. The image processing unit 140 may store in advance recognition information about an object that is likely to be the object of interest of the user, based on the search information of the user. Accordingly, in the case where the user captures the corresponding object, the image processing unit 140 may allow AF to be performed preferentially.

In operation 610, the image processing unit 140 may verify the search information of the user. For example, the image processing unit 140 may verify words found by the user, a pattern of a voice recorded frequently, or the like through a web browser app, a voice recording app, a camera app, or the like.

In operation 620, the image processing unit 140 may obtain additional information associated with the search information of the user. For example, the additional information may be a statistic associated with the words found by the user, a representative image, a search frequency, a search date, a frequency with which the found image is stored in an internal memory, and the like. In the case where the additional information is not stored in the internal memory, the image processing unit 140 may collect related information through an external device (e.g., a server).

In operation 630, the image processing unit 140 may update the object database 230 based on the related information. For this reason, even if the object is not frequently captured by the user, in the case where the object is repeatedly found, the image processing unit 140 may focus the object automatically and preferentially.

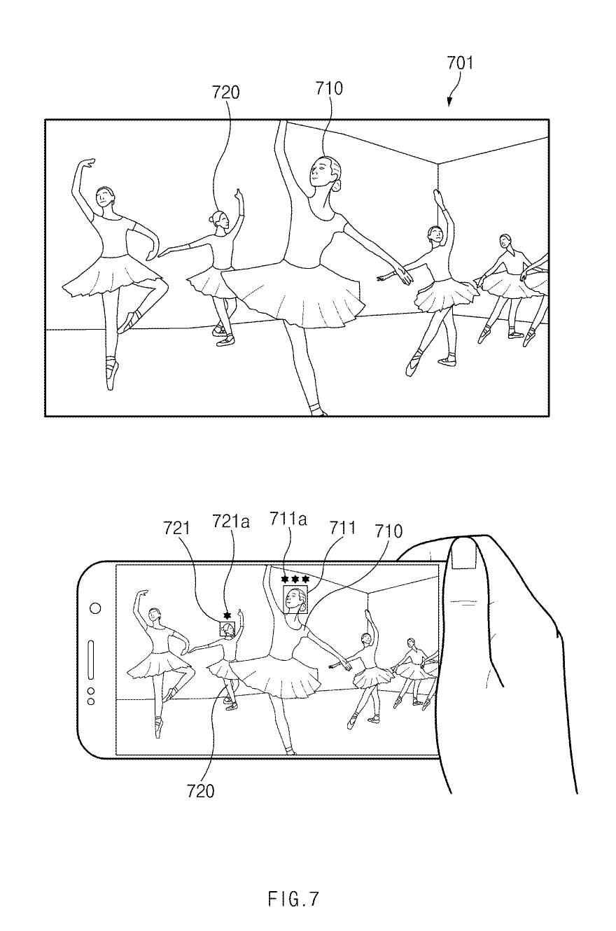

FIG. 7 is a view of a user interface for displaying a priority of an object of interest, according to various embodiments of the present disclosure.

Referring to FIG. 7, in the case where each of two or more objects is determined as an object of interest, the image processing unit 140 may display a priority of each of the objects through the user interface.

In the case where a user starts a capture to capture a plurality of objects included in screen 701, each of the first object 710 and second object 720 may be determined as the object of interest depending on the movement of the electronic device 101 or the priority of an object stored in the object database 230.

The image processing unit 140 may output priority marks 711a and 721a to the first object 710 and the second object 720 independently from AF marks 711 and 721, respectively. The priority marks 711a and 721a may be output depending on the degree of the priority of each of the first object 710 and the second object 720 in various manners of an icon display, a score display, a rank display, an out-focus effect, and the like. For example, the priority marks 711a and 721a may be output in the score display manner. For another example, the priority marks 711a and 721a may be output after being coupled to the AF mark 711 or 721. The AF mark 711 or 721 of an object having a high priority may be displayed to be relatively dark, and the AF mark 711 or 721 of an object having a low priority may be displayed to be relatively light. In another embodiment, the AF mark 711 or 721 of the object having the high priority and the AF mark 711 or 721 of the object having the low priority may be displayed to have different colors.

The user may determine how the object of interest is currently calculated on a Live View, through the priority mark 711a and 721a. As such, the user may estimate the capture result in advance.

If the user performs the capture in the current composition, the capture control unit 240 may determine one-shot capture or AF Bracketing based on the previously calculated distance and depth. If the AF Bracketing is set, the AF Bracketing may be performed automatically when the first object 710 and the second object 720 are not present in the depth. First, an AF point may be focused on the first object 710, which is close to the user, and then the one-shot capture may be performed. Next, the AF point may be focused on the second object 720 and then the one-shot capture may be performed. In the case of a first photo, a photo in which the first object 710 is clear and a periphery of the first object 710 is blurred may be captured. In the case of a second photo, a photo in which the second object 720 is clear and a periphery of the second object 720 is blurred may be captured. In this case, in the case of the first photo, an expose, AWB, color correction, or the like may be performed based on the first object 710. In the case of the second photo, the expose, AWB, color correction, or the like may be performed based on the second object 720.

According to various embodiments, the image processing unit 140 may be configured to preferentially perform the AF, AE, AWB, color correction, or the like on an object of a high priority.

According to various embodiments, in the case where the number of objects, the rank each of which is not less than a specified rank is not less than 2, the image processing unit 140 may calculate the depth of each of the objects. If each of the objects is not within the same depth at the specified AF point, the image processing unit 140 may perform the AF Bracketing.

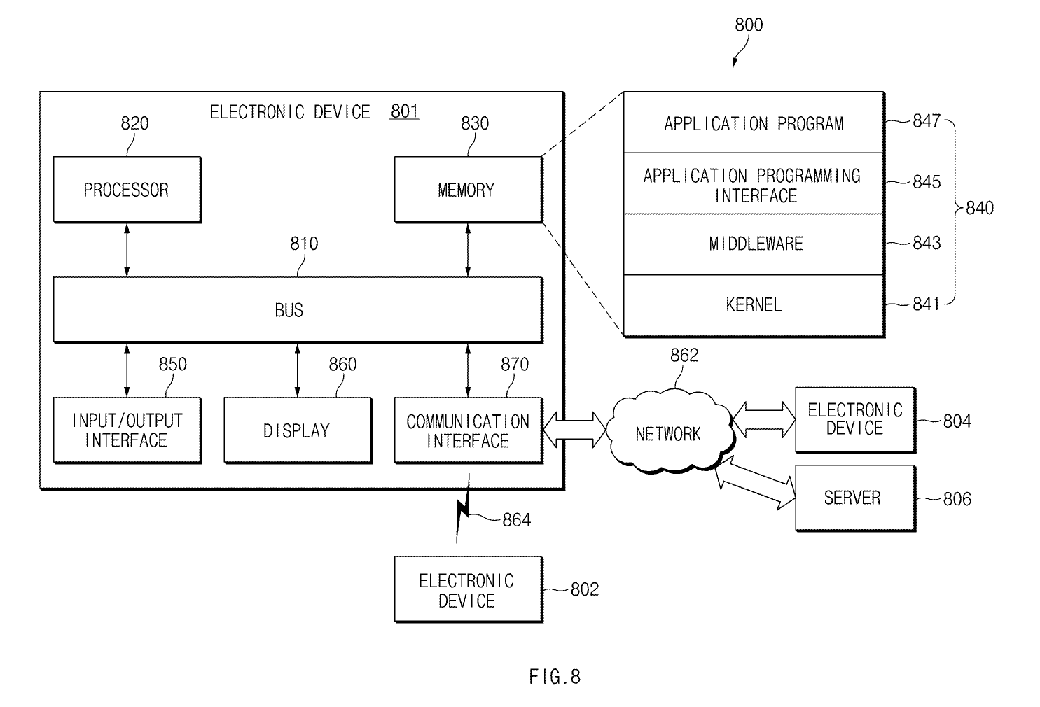

FIG. 8 illustrates an electronic device in a network environment according to an embodiment of the present disclosure of the present disclosure.

Referring to FIG. 8, an electronic device 801 in a network environment 800 according to various embodiments of the present disclosure will be described with reference to FIG. 8. The electronic device 801 may include a bus 810, a processor 820, a memory 830, an input/output interface 850, a display 860, and a communication interface 870. In various embodiments of the present disclosure, at least one of the foregoing elements may be omitted or another element may be added to the electronic device 801.

The bus 810 may include a circuit for connecting the above-mentioned elements 810 to 870 to each other and transferring communications (e.g., control messages and/or data) among the above-mentioned elements.

The processor 820 may include at least one of a CPU, an AP, or a communication processor (CP). The processor 820 may perform data processing or an operation related to communication and/or control of at least one of the other elements of the electronic device 801.

The memory 830 may include a volatile memory and/or a nonvolatile memory. The memory 830 may store instructions or data related to at least one of the other elements of the electronic device 801. According to an embodiment of the present disclosure, the memory 830 may store software and/or a program 840. The program 840 may include, for example, a kernel 841, a middleware 843, an application programming interface (API) 845, and/or an application program (or an application) 847. At least a portion of the kernel 841, the middleware 843, or the API 845 may be referred to as an operating system (OS).

The kernel 841 may control or manage system resources (e.g., the bus 810, the processor 820, the memory 830, or the like) used to perform operations or functions of other programs (e.g., the middleware 843, the API 845, or the application program 847). Furthermore, the kernel 841 may provide an interface for allowing the middleware 843, the API 845, or the application program 847 to access individual elements of the electronic device 801 in order to control or manage the system resources.

The middleware 843 may serve as an intermediary so that the API 845 or the application program 847 communicates and exchanges data with the kernel 841.

Furthermore, the middleware 843 may handle one or more task requests received from the application program 847 according to a priority order. For example, the middleware 843 may assign at least one application program 847 a priority for using the system resources (e.g., the bus 810, the processor 820, the memory 830, or the like) of the electronic device 801. For example, the middleware 843 may handle the one or more task requests according to the priority assigned to the at least one application, thereby performing scheduling or load balancing with respect to the one or more task requests.

The API 845, which is an interface for allowing the application 847 to control a function provided by the kernel 841 or the middleware 843, may include, for example, at least one interface or function (e.g., instructions) for file control, window control, image processing, character control, or the like.

The input/output interface 850 may serve to transfer an instruction or data input from a user or another external device to (an)other element(s) of the electronic device 801. Furthermore, the input/output interface 850 may output instructions or data received from (an)other element(s) of the electronic device 801 to the user or another external device.

The display 860 may include, for example, a liquid crystal display (LCD), a light-emitting diode (LED) display, an organic LED (OLED) display, a microelectromechanical systems (MEMS) display, or an electronic paper display. The display 860 may present various content (e.g., a text, an image, a video, an icon, a symbol, or the like) to the user. The display 860 may include a touch screen, and may receive a touch, gesture, proximity or hovering input from an electronic pen or a part of a body of the user.

The communication interface 870 may set communications between the electronic device 801 and an external device (e.g., a first external electronic device 802, a second external electronic device 804, or a server 806). For example, the communication interface 870 may be connected to a network 862 via wireless communications or wired communications so as to communicate with the external device (e.g., the second external electronic device 804 or the server 806).

The wireless communications may employ at least one of cellular communication protocols such as long-term evolution (LTE), LTE-advance (LTE-A), code division multiple access (CDMA), wideband CDMA (WCDMA), universal mobile telecommunications system (UMTS), wireless broadband (WiBro), or global system for mobile communications (GSM). The wireless communications may include, for example, a short-range communications 864. The short-range communications may include at least one of wireless fidelity (Wi-Fi), Bluetooth (BT), near field communication (NFC), magnetic stripe transmission (MST), or GNSS.

The MST may generate pulses according to transmission data and the pulses may generate electromagnetic signals. The electronic device 801 may transmit the electromagnetic signals to a reader device such as a POS (point of sales) device. The POS device may detect the magnetic signals by using a MST reader and restore data by converting the detected electromagnetic signals into electrical signals.

The GNSS may include, for example, at least one of global positioning system (GPS), global navigation satellite system (GLONASS), BeiDou navigation satellite system (BeiDou), or Galileo, the European global satellite-based navigation system according to a use area or a bandwidth. Hereinafter, the term “GPS” and the term “GNSS” may be interchangeably used. The wired communications may include at least one of universal serial bus (USB), high definition multimedia interface (HDMI), recommended standard 832 (RS-232), plain old telephone service (POTS), or the like. The network 862 may include at least one of telecommunications networks, for example, a computer network (e.g., local area network (LAN) or wide area network (WAN)), the Internet, or a telephone network.

The types of the first external electronic device 802 and the second external electronic device 804 may be the same as or different from the type of the electronic device 801. According to an embodiment of the present disclosure, the server 806 may include a group of one or more servers. A portion or all of operations performed in the electronic device 801 may be performed in one or more other electronic devices (e.g., the first electronic device 802, the second external electronic device 804, or the server 806). When the electronic device 801 should perform a certain function or service automatically or in response to a request, the electronic device 801 may request at least a portion of functions related to the function or service from another device (e.g., the first electronic device 802, the second external electronic device 804, or the server 806) instead of or in addition to performing the function or service for itself The other electronic device (e.g., the first electronic device 802, the second external electronic device 804, or the server 806) may perform the requested function or additional function, and may transfer a result of the performance to the electronic device 801. The electronic device 801 may use a received result itself or additionally process the received result to provide the requested function or service. To this end, for example, a cloud computing technology, a distributed computing technology, or a client-server computing technology may be used.

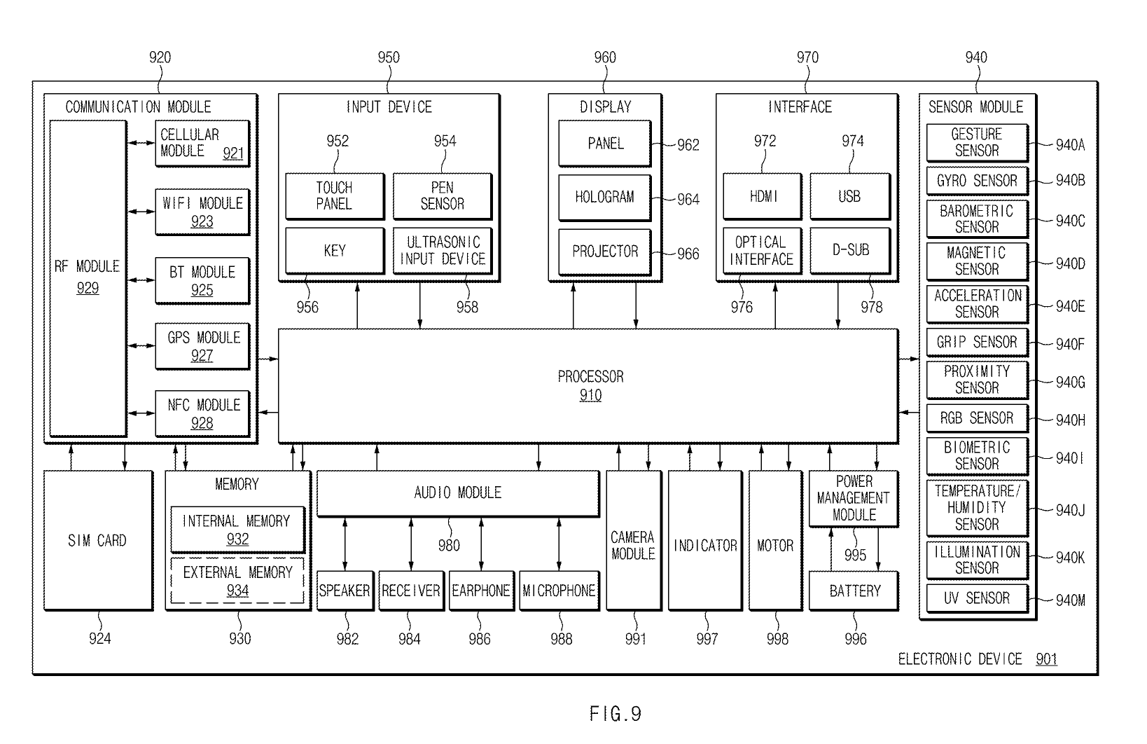

FIG. 9 is a block diagram illustrating an electronic device according to an embodiment of the present disclosure of the present disclosure.

Referring to FIG. 9, an electronic device 901 may include, for example, a part or the entirety of the electronic device 801 illustrated in FIG. 8. The electronic device 901 may include at least one processor (e.g., AP) 910, a communication module 920 (transceiver), a subscriber identification module (SIM) 924, a memory 930, a sensor module 940, an input device 950, a display 960, an interface 970, an audio module 980, a camera module 991, a power management module 995, a battery 996, an indicator 997, and a motor 998.

The processor 910 may run an operating system (OS) or an application program so as to control a plurality of hardware or software elements connected to the processor 910, and may process various data and perform operations. The processor 910 may be implemented with, for example, a system on chip (SoC). According to an embodiment of the present disclosure, the processor 910 may further include a graphic processing unit (GPU) and/or an image signal processor (ISP). The processor 910 may include at least a portion (e.g., a cellular module 921) of the elements illustrated in FIG. 9. The processor 910 may load, on a volatile memory, an instruction or data received from at least one of other elements (e.g., a nonvolatile memory) to process the instruction or data, and may store various data in a nonvolatile memory.

The communication module 920 may have a configuration that is the same as or similar to that of the communication interface 870 of FIG. 8. The communication module 920 may include, for example, a cellular module 921, a Wi-Fi module 923, a BT module 925, a GPS module 927 (e.g., a GNSS module, a GLONASS module, a BeiDou module, or a Galileo module), a NFC module 928, and a radio frequency (RF) module 929.

The cellular module 921 may provide, for example, a voice call service, a video call service, a text message service, or an Internet service through a communication network. The cellular module 921 may identify and authenticate the electronic device 901 in the communication network using the subscriber identification module (SIM) 924 (e.g., a SIM card). The cellular module 921 may perform at least a part of functions that may be provided by the processor 910. The cellular module 921 may include a communication processor (CP).

Each of the Wi-Fi module 923, the BT module 925, the GNSS module 927 and the NFC module 928 may include, for example, a processor for processing data transmitted/received through the modules. According to some various embodiments of the present disclosure, at least a part (e.g., two or more) of the cellular module 921, the Wi-Fi module 923, the BT module 925, the GNSS module 927, and the NFC module 928 may be included in a single integrated chip (IC) or IC package.

The RF module 929 may transmit/receive, for example, communication signals (e.g., RF signals). The RF module 929 may include, for example, a transceiver, a power amp module (PAM), a frequency filter, a low noise amplifier (LNA), an antenna, or the like. According to another embodiment of the present disclosure, at least one of the cellular module 921, the Wi-Fi module 923, the BT module 925, the GNSS module 927, or the NFC module 928 may transmit/receive RF signals through a separate RF module.

The SIM 924 may include, for example, an embedded SIM and/or a card containing the subscriber identity module, and may include unique identification information (e.g., an integrated circuit card identifier (ICCID)) or subscriber information (e.g., international mobile subscriber identity (IMSI)).

The memory 930 (e.g., the memory 830) may include, for example, an internal memory 932 or an external memory 934. The internal memory 932 may include at least one of a volatile memory (e.g., a dynamic RAM (DRAM), a static RAM (SRAM), a synchronous dynamic RAM (SDRAM), or the like), a nonvolatile memory (e.g., a one-time programmable ROM (OTPROM), a programmable ROM (PROM), an erasable and programmable ROM (EPROM), an electrically erasable and programmable ROM (EEPROM), a mask ROM, a flash ROM, a flash memory (e.g., a NAND flash memory, a NOR flash memory, or the like)), a hard drive, or a solid state drive (SSD).

The external memory 934 may include a flash drive such as a compact flash (CF), a secure digital (SD), a micro-SD, a mini-SD, an extreme digital (xD), a MultiMediaCard (MMC), a memory stick, or the like. The external memory 934 may be operatively and/or physically connected to the electronic device 901 through various interfaces.

The sensor module 940 may, for example, measure physical quantity or detect an operation state of the electronic device 901 so as to convert measured or detected information into an electrical signal. The sensor module 940 may include, for example, at least one of a gesture sensor 940A, a gyro sensor 940B, a barometric pressure sensor 940C, a magnetic sensor 940D, an acceleration sensor 940E, a grip sensor 940F, a proximity sensor 940G, a color sensor 940H (e.g., a red/green/blue (RGB) sensor), a biometric sensor 940I, a temperature/humidity sensor 940J, an illumination sensor 940K, or an ultraviolet (UV) sensor 940M. Additionally or alternatively, the sensor module 940 may include, for example, an olfactory sensor (E-nose sensor), an electromyography (EMG) sensor, an electroencephalogram (EEG) sensor, an electrocardiogram (ECG) sensor, an infrared (IR) sensor, an iris recognition sensor, and/or a fingerprint sensor. The sensor module 940 may further include a control circuit for controlling at least one sensor included therein. In some various embodiments of the present disclosure, the electronic device 901 may further include a processor configured to control the sensor module 940 as a part of the processor 910 or separately, so that the sensor module 940 is controlled while the processor 910 is in a sleep state.

The input device 950 may include, for example, a touch panel 952, a (digital) pen sensor 954, a key 956, or an ultrasonic input device 958. The touch panel 952 may employ at least one of capacitive, resistive, infrared (IR), and ultraviolet (UV) sensing methods. The touch panel 952 may further include a control circuit. The touch panel 952 may further include a tactile layer so as to provide a haptic feedback to a user.

The (digital) pen sensor 954 may include, for example, a sheet for recognition which is a part of a touch panel or is separate. The key 956 may include, for example, a physical button, an optical button, or a keypad. The ultrasonic input device 958 may sense ultrasonic waves generated by an input tool through a microphone 988 so as to identify data corresponding to the ultrasonic waves sensed.

The display 960 (e.g., the display 860) may include a panel 962, a hologram device 964, or a projector 966. The panel 962 may have a configuration that is the same as or similar to that of the display 860 of FIG. 8. The panel 962 may be, for example, flexible, transparent, or wearable. The panel 962 and the touch panel 952 may be integrated into a single module. The hologram device 964 may display a stereoscopic image in a space using a light interference phenomenon. The projector 966 may project light onto a screen so as to display an image. The screen may be disposed in the inside or the outside of the electronic device 901. According to an embodiment of the present disclosure, the display 960 may further include a control circuit for controlling the panel 962, the hologram device 964, or the projector 966.

The interface 970 may include, for example, an HDMI 972, a USB 974, an optical interface 976, or a D-sub 978. The interface 970, for example, may be included in the communication interface 870 illustrated in FIG. 8. Additionally or alternatively, the interface 970 may include, for example, a mobile high-definition link (MHL) interface, an SD card/multi-media card (MMC) interface, or an infrared data association (IrDA) interface.

The audio module 980 may convert, for example, a sound into an electrical signal or vice versa. At least a portion of elements of the audio module 980 may be included in the input/output interface 850 illustrated in FIG. 8. The audio module 980 may process sound information input or output through a speaker 982, a receiver 984, an earphone 986, or the microphone 988.

The camera module 991 is, for example, a device for shooting a still image or a video. According to an embodiment of the present disclosure, the camera module 991 may include at least one image sensor (e.g., a front sensor or a rear sensor), a lens, an image signal processor (ISP), or a flash (e.g., an LED or a xenon lamp).

The power management module 995 may manage power of the electronic device 901. According to an embodiment of the present disclosure, the power management module 995 may include a power management integrated circuit (PMIC), a charger integrated circuit (IC), or a battery or gauge. The PMIC may employ a wired and/or wireless charging method. The wireless charging method may include, for example, a magnetic resonance method, a magnetic induction method, an electromagnetic method, or the like. An additional circuit for wireless charging, such as a coil loop, a resonant circuit, a rectifier, or the like, may be further included. The battery gauge may measure, for example, a remaining capacity of the battery 996 and a voltage, current or temperature thereof while the battery is charged. The battery 996 may include, for example, a rechargeable battery and/or a solar battery.

The indicator 997 may display a specific state of the electronic device 901 or a part thereof (e.g., the processor 910), such as a booting state, a message state, a charging state, or the like. The motor 998 may convert an electrical signal into a mechanical vibration, and may generate a vibration or haptic effect. Although not illustrated, a processing device (e.g., a GPU) for supporting a mobile TV may be included in the electronic device 901. The processing device for supporting a mobile TV may process media data according to the standards of digital multimedia broadcasting (DMB), digital video broadcasting (DVB), MediaFLO™, or the like.

Each of the elements described herein may be configured with one or more components, and the names of the elements may be changed according to the type of an electronic device. In various embodiments of the present disclosure, an electronic device may include at least one of the elements described herein, and some elements may be omitted or other additional elements may be added. Furthermore, some of the elements of the electronic device may be combined with each other so as to form one entity, so that the functions of the elements may be performed in the same manner as before the combination.

According to various embodiments, an electronic device includes a lens part configured to collect light from an outside, an image sensor configured to change light passing through the lens part to an electrical signal, a memory, and an image processing unit configured to process an image signal of the image sensor, wherein the image processing unit is configured to collect first image data through the image sensor at a first time, collect first recognition information about a plurality of objects recognized from the first image data, collect second image data through the image sensor at a second time, collect second recognition information about an object recognized from the second image data, and determine an object of interest of a user based on a difference between the first recognition information and the second recognition information.

According to various embodiments, the image processing unit is configured to generate a control signal for controlling the lens part or the image sensor, by using the determined object of interest.

According to various embodiments, the image processing unit is configured to perform at least one of auto focus (AF), auto exposure (AE), auto white balance (AWB), or color correction by using the control signal.

According to various embodiments, the memory stores priority information about an external object. And the image processing unit is configured to determine the object of interest before the second time, based on the first recognition information or the priority information, and determine the object of interest after the second time, based on the difference between the first recognition information and the second recognition information.

According to various embodiments, the image processing unit is configured to if a capture input associated with a still image occurs, update priority information based on the first recognition information and the second recognition information.

According to various embodiments, the image processing unit is configured to update the priority information about an object recognized from an image stored in response to the capture input.

According to various embodiments, the electronic device further includes a communication module, wherein the image processing unit is configured to transmit the updated priority information to an external device by using the communication module.

According to various embodiments, the image processing unit is configured to if a capture end input or a storage input associated with a video occurs, update priority information based on the first recognition information and the second recognition information.

According to various embodiments, the image processing unit is configured to update the priority information about an object recognized from the video stored in response to the capture end input or the storage input.

According to various embodiments, the electronic device further includes at least one sensor configured to obtain information associated with the electronic device or a situation of a periphery of the electronic device.

According to various embodiments, the image processing unit is configured to determine whether the electronic device moves by a specified range or more or the electronic device rotates by the specified range or more, through the at least one sensor.

According to various embodiments, the image processing unit is configured to compare the first image with the second image to extract movement information of an object, extract movement information of the electronic device through the at least one sensor, and if the movement information of the object is synchronized with the movement information of the electronic device, set a priority of the object to be high.

According to various embodiments, the image processing unit is configured to if movement of the electronic device that is not less than a specified range is sensed through the at least one sensor between the first time and the second time, determine the object of interest of the user based on the difference between the first recognition information and the second recognition information.

According to various embodiments, the priority information includes at least part of the priority information, a capture frequency, composition information, information about a capture date, or capture location information of the object.

According to various embodiments, the image processing unit is configured to update the priority information based on search information of the user.

According to various embodiments, the image processing unit is configured to continuously receive an image signal through the image sensor between the first time and the second time.

According to various embodiments, the electronic device further includes a display configured to output contents, wherein the image processing unit is configured to display information associated with a priority of an object included in an image output through the display, at a third time after the second time.

While the present disclosure has been shown and described with reference to various embodiments thereof, it will be understood by those skilled in the art that various changes in form and details may be made therein without departing from the spirit and scope of the present disclosure as defined by the appended claims and their equivalents.

What is claimed is:

1. An electronic device comprising:
a lens part configured to collect light from outside of the electronic device;
an image sensor configured to change light passing through the lens part to an electrical signal;
a memory; and
at least one image processor for processing an image signal of the image sensor configured to:
collect first image data through the image sensor at a first time,
collect first recognition information about a plurality of objects recognized from the first image data,
collect second image data through the image sensor at a second time,
collect second recognition information about an object recognized from the second image data, and
determine an object of interest of a user based on a difference between the first recognition information and the second recognition information.

2. The electronic device of claim 1, wherein the at least one image processor is further configured to:
generate a control signal for controlling the lens part or the image sensor, by using the determined object of interest.

3. The electronic device of claim 2, wherein the at least one image processor is further configured to:
perform at least one of auto focus (AF), auto exposure (AE), auto white balance (AWB), or color correction by using the control signal.

4. The electronic device of claim 1,
wherein the memory stores priority information about an external object, and
wherein the at least one image processor is further configured to:
determine the object of interest before the second time, based on the first recognition information or the priority information, and
determine the object of interest after the second time, based on the difference between the first recognition information and the second recognition information.

5. The electronic device of claim 1, wherein, if a capture input associated with a still image occurs, the at least one image processor is further configured to:
update priority information based on the first recognition information and the second recognition information.

6. The electronic device of claim 5, wherein the at least one image processor is further configured to:
update the priority information about an object recognized from an image stored in response to the capture input.

7. The electronic device of claim 5, further comprising:
a transceiver,
wherein the at least one image processor is further configured to transmit the updated priority information to an external device by using the transceiver.

8. The electronic device of claim 1, wherein, if a capture end input or a storage input associated with a video occurs, the at least one image processor is further configured to:
update priority information based on the first recognition information and the second recognition information.

9. The electronic device of claim 8, wherein the at least one image processor is further configured to:
update the priority information about an object recognized from the video stored in response to the capture end input or the storage input.

10. The electronic device of claim 1, further comprising:
at least one sensor configured to obtain information associated with the electronic device or a situation of a periphery of the electronic device.

11. The electronic device of claim 10, wherein the at least one image processor is further configured to:
determine whether the electronic device moves by a specified range or more or the electronic device rotates by the specified range or more, through the at least one sensor.

12. The electronic device of claim 10, wherein the at least one image processor is further configured to:
compare the first image with the second image to extract movement information of an object,
extract movement information of the electronic device through the at least one sensor, and
if the movement information of the object is synchronized with the movement information of the electronic device, set a priority of the object to be high.

13. The electronic device of claim 10, wherein, if movement of the electronic device that is not less than a specified range is sensed through the at least one sensor between the first time and the second time, the at least one image processor is further configured to:
determine the object of interest of the user based on the difference between the first recognition information and the second recognition information.

14. The electronic device of claim 4, wherein the priority information includes at least part of the priority information, a capture frequency, composition information, information about a capture date, or capture location information of the object.

15. The electronic device of claim 4, wherein the at least one image processor is further configured to:
update the priority information based on search information of the user.

16. The electronic device of claim 1, wherein the at least one image processor is further configured to:
continuously receive an image signal through the image sensor between the first time and the second time.

17. The electronic device of claim 1, further comprising:
a display configured to output contents,
wherein the at least one image processor is further configured to:
display information associated with a priority of an object included in an image output through the display, at a third time after the second time.

18. A method for image processing performed in an electronic device, the method comprising:
collecting a first image through an image sensor at a first time;
collecting first recognition information about a plurality of objects recognized from the first image;
collecting a second image through the image sensor at a second time;
collecting second recognition information about an object recognized from the second image; and
determining an object of interest of a user based on a difference between the first recognition information and the second recognition information.

19. The method of claim 18, further comprising:
generating a control signal for controlling a lens part or the image sensor, by using the determined object of interest.

20. The method of claim 18, further comprising:
if a capture input associated with a still image is generated, updating priority information about an external object stored in a memory based on the first recognition information and the second recognition information; and
if a capture end input or a storage input associated with a video is generated, updating priority information about an external object stored in a memory based on the first recognition information and the second recognition information.
